(19) United States
(12) Patent Application Publication
(10) Pub. No.: US 2016/0069964 A1
(43) Pub. Date: Mar. 10, 2016

(54) BATTERY STATE DETECTION DEVICE

(71) Applicant: Yazaki Corporation, Tokyo (JP)

(72) Inventors: Nobuyuki Takahashi, Shizuoka (JP); Takahiro Syouda, Shizuoka (JP)

(21) Appl. No.: 14/942,508

(22) Filed: Nov. 16, 2015

Related U.S. Application Data
(63) Continuation of application No. PCT/JP2014/066684, filed on Jun. 24, 2014.

(30) Foreign Application Priority Data
Jun. 26, 2013 (JP) 2013-133368

(51) Int. Cl. G01R 31/36; H01M 10/48

(52) U.S. Cl. CPC G01R 31/3679; H01M 10/48; G01R 31/3648

(57) ABSTRACT

In a battery state detection device, a μCOM detects that, during charge by a charge part, a voltage between both electrodes of a secondary battery has reached a predetermined measurement start voltage set higher than a voltage between the both electrodes of the secondary battery at the time of complete discharge, and detects that, during the charge by the charge part, the voltage between the both electrodes of the secondary battery has reached a predetermined measurement finish voltage set higher than the measurement start voltage. Then, the μCOM measures an amount of integrated power given to the secondary battery in a period from the detection of the measurement start voltage to the detection of the measurement finish voltage, and detects an SOH of the secondary battery based on the amount of integrated power measured by integrated power amount measurement unit.

### TECHNICAL FIELD

The present invention relates to a battery state detection device for detecting a state of a secondary battery.

### BACKGROUND ART

For example, as a power source of an electric motor, a secondary battery, such as a lithium ion rechargeable battery or a nickel-metal hydride rechargeable battery, is mounted on various kinds of vehicles, such as an electric vehicle (EV) travelled using the electric motor and a hybrid vehicle (HEV) travelled using both an engine and the electric motor.

It is known that deterioration of such a secondary battery progresses due to repetition of charging and discharging and that a storable capacity (a current capacity, a power capacity, or the like) gradually decreases. Moreover, in the electric vehicle or the like using the secondary battery, the storable capacity is obtained by detecting a degree of deterioration as a state of the secondary battery, and a travelable distance of the vehicle with the secondary battery, a life of the secondary battery, or the like is calculated.

An SOH (State of Health), which is a ratio of a present storable capacity to an initial storable capacity, is one of indexes for indicating the degree of deterioration of the secondary battery. An example of a technique for detecting such an SOH of the secondary battery is disclosed in Patent Literature 1 and the like. In a method disclosed in Patent Literature 1, after a secondary battery serving as a detection target of the SOH is temporarily discharged completely, constant current charge is performed up to full charge, and the SOH is detected based on duration time of this constant current charge.

### CITATION LIST

### Patent Literature

Patent Literature 1: JP 2007-205880 A

### SUMMARY OF INVENTION

### Technical Problem

However, in the method disclosed in Patent Literature 1, since it is necessary to completely discharge the secondary battery, it is necessary to provide discharge unit and the like. Accordingly, there are problems in that manufacturing cost increases and size of a device increases. Further, since it is necessary to charge the secondary battery up to full charge after the battery is completely discharged, there is a problem in that it takes a long time to detect the SOH.

The present invention is made to solve such problems. In other words, an object of the present invention is to provide a battery state detection device capable of effectively suppressing increase in manufacturing cost and increase in size of the device and detecting a state of a secondary battery in a shorter time.

### Solution to Problem

As a result of keen examination of a storable capacity of a secondary battery, the present inventors have found a correlation between a storable capacity and an amount of power, an amount of current given to the secondary battery in a part of a whole period from the time of complete discharge to the time of full charge, and have reached the present invention.

To achieve the above object, the invention according to a first aspect is a battery state detection device for detecting a state of a secondary battery, including: charge unit that charges the secondary battery by feeding a predetermined charging current to the secondary battery; measurement start voltage detection unit that detects that, during the charge by the charge unit, a voltage between both electrodes of the secondary battery has reached a predetermined measurement start voltage which is higher than a voltage between the both electrodes of the secondary battery at a time of complete discharge; measurement finish voltage detection unit that detects that, during the charge by the charge unit, the voltage between the both electrodes of the secondary battery has reached a predetermined measurement finish voltage which is higher than the measurement start voltage; integrated power amount measurement unit that measures an amount of integrated power given to the secondary battery in a period from the detection of the measurement start voltage to the detection of the measurement finish voltage; and battery state detection unit that detects a state of the secondary battery based on the amount of integrated power measured by the integrated power amount measurement unit.

To achieve the above object, the invention according to a second aspect is a battery state detection device for detecting a state of a secondary battery, including: charge unit that charges the secondary battery by feeding a predetermined charging current to the secondary battery; measurement start voltage detection unit that detects that, during the charge by the charge unit, a voltage between both electrodes of the secondary battery has reached a predetermined measurement start voltage which is higher than a voltage between the both electrodes of the secondary battery at a time of complete discharge; measurement finish voltage detection unit that detects that, during the charge by the charge unit, the voltage between the both electrodes of the secondary battery has reached a predetermined measurement finish voltage which is higher than the measurement start voltage; integrated current amount measurement unit that measures an amount of integrated current flowed into the secondary battery in a period from the detection of the measurement start voltage to the detection of the measurement finish voltage; and battery state detection unit that detects a state of the secondary battery based on the amount of integrated current measured by the integrated current amount measurement unit.

### Advantageous Effects of Invention

According to the first aspect of the present invention, charge unit charges the secondary battery by feeding a predetermined charging current thereto. Measurement start voltage detection unit detects that, during the charge by the charge unit, a voltage between both electrodes of the secondary battery has reached a predetermined measurement start voltage which is higher than a voltage between the both electrodes of the secondary battery at the time of complete discharge. Measurement finish voltage detection unit detects that, during the charge by the charge unit, the voltage between the both electrodes of the secondary battery has reached a predetermined measurement finish voltage which is higher than the measurement start voltage. Integrated power amount measurement unit measures an amount of integrated power given to the secondary battery in a period from the detection of the measurement start voltage to the detection of the measurement finish voltage. Then, battery state detection unit detects a state of the secondary battery based on the amount of integrated power measured by the integrated power amount measurement unit. Since it has been done in this way, in the secondary battery being charged, the amount of integrated power given to the secondary battery is measured in a part of a period from the time of complete discharge to the time of full charge, and the state of the secondary battery is detected based on this amount of integrated power. Accordingly, it is not necessary to provide discharge unit, and further, it is not necessary to measure over a whole period from the time of complete discharge to the time of full charge (including a charge state close to the full charge). As a result, it is possible to effectively suppress increase in manufacturing cost and increase in size of the device and to detect the state of the secondary battery in a shorter time.

According to the second aspect of the present invention, charge unit charges the secondary battery by feeding a predetermined charging current thereto. Measurement start voltage detection unit detects that, during the charge by the charge unit, a voltage between both electrodes of the secondary battery has reached a predetermined measurement start voltage which is higher than a voltage between the both electrodes of the secondary battery at the time of complete discharge. Measurement finish voltage detection unit detects that, during the charge by the charge unit, the voltage between the both electrodes of the secondary battery has reached a predetermined measurement finish voltage which is higher than the measurement start voltage. Integrated current amount measurement unit measures an amount of integrated current flowed into the secondary battery in a period from the detection of the measurement start voltage to the detection of the measurement finish voltage. Then, battery state detection unit detects a state of the secondary battery based on the amount of integrated current measured by the integrated current amount measurement unit. Since it has been done in this way, in the secondary battery being charged, the amount of integrated current given to the secondary battery is measured in a part of a period from the time of complete discharge to the time of full charge, and the state of the secondary battery is detected based on this amount of integrated current. Accordingly, it is not necessary to provide discharge unit, and further, it is not necessary to measure over a whole period from the time of complete discharge to the time of full charge (including a charge state close to the full charge). As a result, it is possible to effectively suppress increase in manufacturing cost and increase in size of the device and to detect the state of the secondary battery in a shorter time.

### BRIEF DESCRIPTION OF DRAWINGS

FIG. 1 is a diagram that illustrates a schematic configuration of a battery state detection device according to a first embodiment of the present invention.

FIG. 2 is a flowchart that illustrates an example of battery state detection processing 1 (power integration) executed by a CPU of a microcomputer included in the battery state detection device in FIG. 1.

FIG. 3 is a flowchart that illustrates an example of battery state detection processing 2 (current integration) executed by a CPU of a microcomputer included in a battery state detection device according to a second embodiment of the present invention.

FIG. 4 is a graph that illustrates, in a plurality of secondary batteries having different degrees of deterioration, a relation between an amount of current flowed to the secondary battery and a voltage between both electrodes of the secondary battery.

FIG. 5 is a graph that illustrates a relation between an amount of power given to the secondary battery and a degree of deterioration of the secondary battery.

FIG. 6 is a graph that illustrates a relation between an amount of current flowed to the secondary battery and the degree of deterioration of the secondary battery.

FIGS. 7A and 7B are graphs that schematically illustrate a relation between the amount of current flowed to the secondary battery and the voltage between the both electrodes of the secondary battery. FIG. 7A is a graph of the secondary battery having no deterioration, and FIG. 7B is a graph of the secondary battery having deterioration.

### DESCRIPTION OF EMBODIMENTS

The present inventors prepared a plurality of secondary batteries (lithium ion batteries) to deteriorate a part of the secondary batteries (the lithium ion batteries) by actually performing a charge and discharge cycle repeatedly thereon. Then, charge was performed on this plurality of secondary batteries from a complete discharge state to a complete charge state, and an SOH (a ratio of a present storable power capacity to a storable power capacity in an initial state) of each secondary battery was calculated based on an amount of power actually given. Accordingly, the secondary batteries with three degrees of deterioration, i.e., no deterioration (SOH=100%), small deterioration (SOH=94%), and large deterioration (SOH=90%) were obtained. Then, a relation between the SOH and the amount of power, an amount of current given to the secondary battery was confirmed on these secondary batteries in a part of an interval from the complete discharge state to the complete charge state.

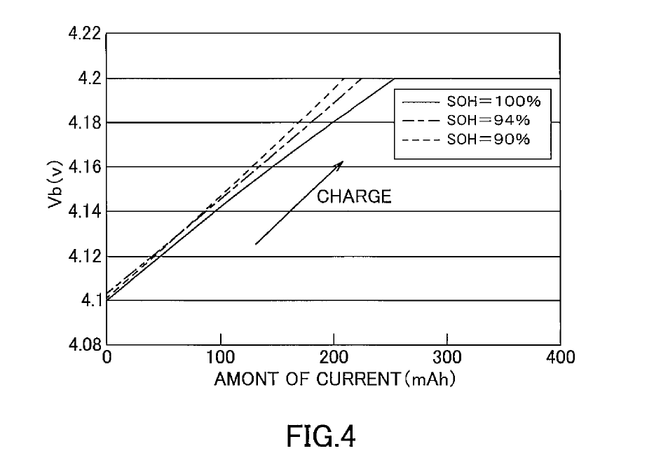

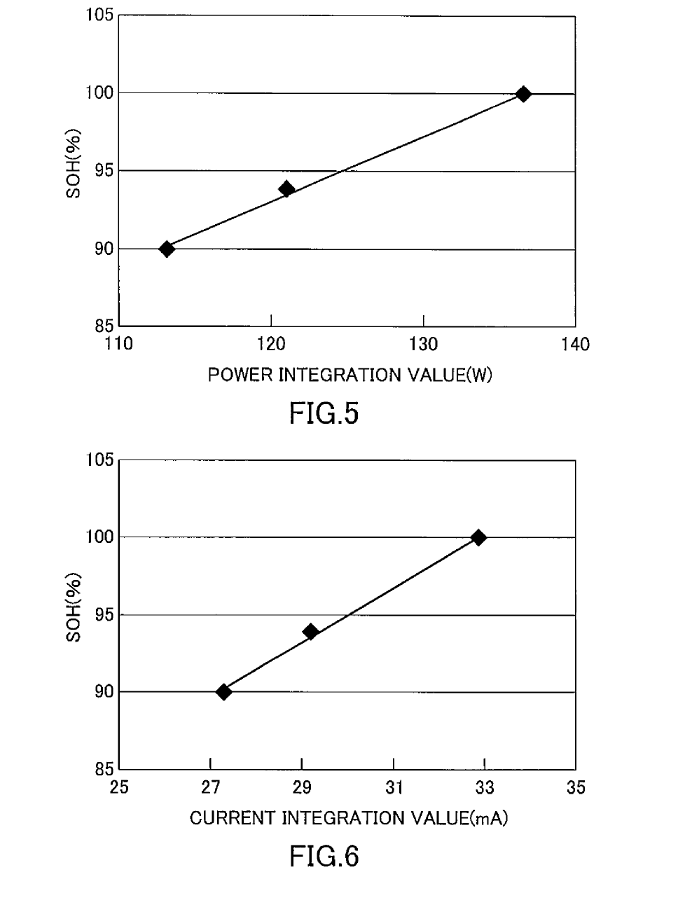

Specifically, the amount of current flowed to the secondary battery was measured in a period when a voltage between both electrodes of the secondary battery reached a predetermined measurement finish voltage Vth (4.2 V) from a predetermined measurement start voltage Vtl (4.1 V) higher than a voltage at the time of complete discharge (3.0 V). FIG. 4 illustrates a relation between the amount of current flowed to the secondary battery and the voltage of the secondary battery. Further, FIG. 5 illustrates a relation between the SOH and the amount of power (a power integration value, i.e., an amount of integrated power) given to the secondary battery from the measurement start voltage Vtl to the measurement finish voltage Vth. Further, FIG. 6 illustrates a relation between the SOH and the amount of current (a current integration value, i.e., an amount of integrated current) flowed to the secondary battery from the measurement start voltage Vtl to the measurement finish voltage Vth. From FIG. 5, it is found that the higher the SOH, the larger the amount of power given to the secondary battery. From FIG. 6, it is found that the higher the SOH, the larger the amount of current flowed to the secondary battery.

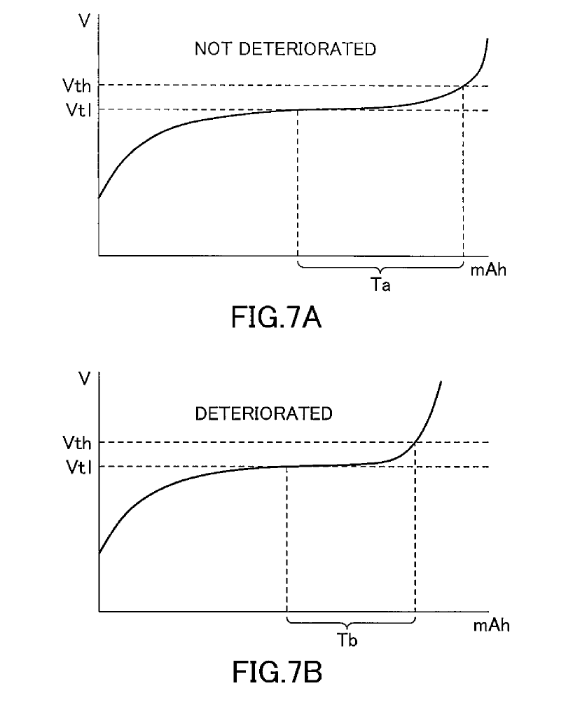

In other words, as schematically illustrated in FIGS. 7A and 7B, the amount of power given to the secondary battery having no deterioration and the amount of current flowed to the secondary battery in an interval Ta from the measurement start voltage Vtl to the measurement finish voltage Vth are larger than the amount of power given to the secondary battery having deterioration and the amount of current flowed to the secondary battery in an interval Tb from the measurement start voltage Vtl to the measurement finish voltage Vth. Accordingly, there are a correlation between the SOH and the amount of power given to the secondary battery (the amount of integrated power) and a correlation between the SOH and the amount of current flowed to the secondary battery (the amount of integrated current) in a part of the interval from the complete discharge state to the complete charge state. As a result, the SOH can be obtained based on these amount of integrated power and amount of integrated current.

### First Embodiment

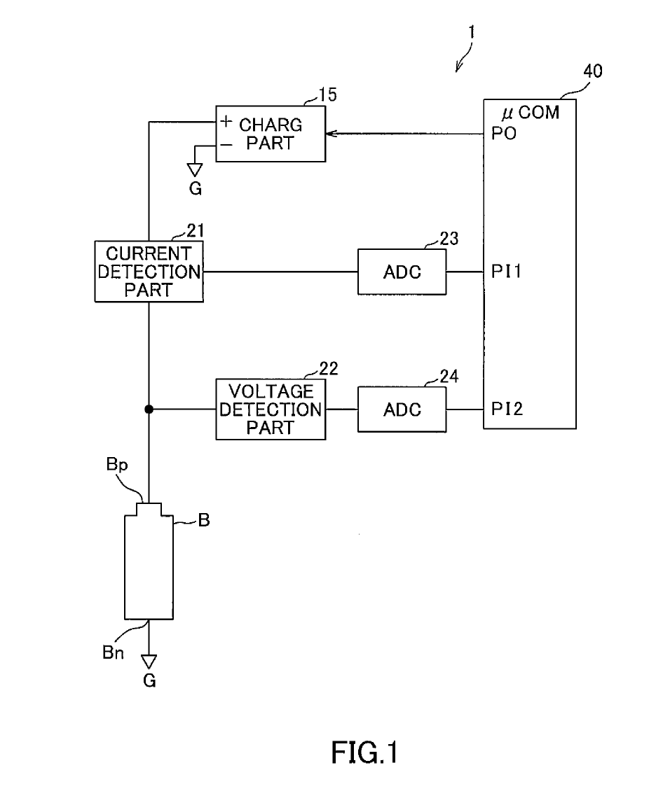

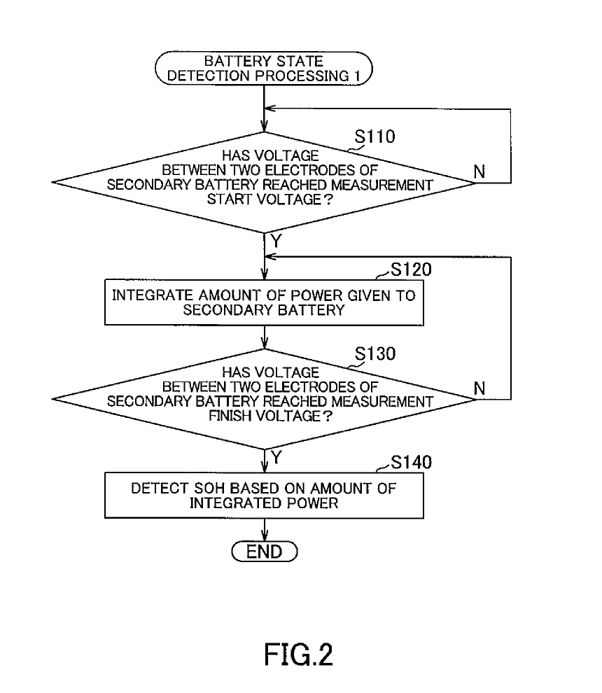

Hereinafter, a battery state detection device according to a first embodiment of the present invention will e described with reference to FIGS. 1, 2.

FIG. 1 is a diagram that illustrates a schematic configuration of the battery state detection device according to the first embodiment of the present invention. FIG. 2 is a flowchart that illustrates an example of battery state detection processing 1 (power integration) executed by a CPU of a microcomputer included in the battery state detection device in FIG. 1.

The battery state detection device of the present embodiment is, for example, mounted on an electric vehicle, connected between electrodes of a secondary battery included in the electric vehicle, and detects an SOH of the secondary battery as a state of the secondary battery. Needless to say, the battery state detection device may be applied to a device, a system, or the like including a secondary battery other than the electric vehicle.

As illustrated in FIG. 1, a battery state detection device (indicated by a reference sign 1 in the drawing) of the present embodiment has a charge part 15, a current detection part 21, a voltage detection part 22, a first analog-digital converter 23 (hereinafter referred to as a “first ADC 23”), a second analog-digital converter 24 (hereinafter referred to as a “second ADC 24”), and a microcomputer 40 (hereinafter referred to as a “μCOM 40”).

The charge part 15 is connected between a positive electrode Bp of a secondary battery B and a reference potential G (i.e., a negative electrode Bn of the secondary battery B), and is provided so as to be able to feed charging current to the secondary battery B when charging the secondary battery B. The charge part 15 is connected to the μCOM 40, which will be described below, and charges the secondary battery B by feeding the charging current thereto according to a control signal from the μCOM 40. The charge part 15 corresponds to charge unit.

The current detection part 21 is provided in series between one terminal of the charge part 15 and the positive electrode Bp of the secondary battery B, detects a current value I flowing to the secondary battery B, and outputs a signal whose voltage changes according to a size of the current (a current signal).

The voltage detection part 22 outputs a signal according to a voltage (voltage signal) between the positive electrode Bp of the secondary battery B and the reference potential G (i.e., the negative electrode Bn of the secondary battery B). In the present embodiment, for example, the voltage detection part 22 is configured by a plurality of fixed resistors and the like that divides the voltage between the both electrodes of the secondary battery B so as to meet a voltage range that can be input to the second ADC 24, which will be described below.

The first analog-digital converter 23 (the first ADC 23) quantizes the signal output from the current detection part 21 and outputs a signal that indicates a digital value corresponding to a voltage value of the signal. Similarly, the second analog-digital converter 24 (the second ADC 24) quantizes the signal output from the voltage detection part 22 and outputs a signal that indicates a digital value corresponding to a voltage value of the signal. In the present embodiment, the first ADC 23 and the second ADC 24 are mounted as separate electronic components. However, the present invention is not limited to this. For example, the first ADC 23 and the second ADC 24 may quantize the respective signals by using an analog-digital conversion part incorporated in the μCOM 40, which will be described below.

The μCOM 40 is configured by incorporating a CPU, a ROM, a RAM, a timer, and the like and controls the entire battery state detection device 1. The ROM previously stores a control program for functioning the CPU as various kinds of unit, such as measurement start voltage detection unit, measurement finish voltage detection unit, integrated power amount measurement unit, or battery state detection unit. The CPU functions as the above-described various kinds of unit by executing this control program.

Further, various kinds of parameters, such as an initial power capacity Pf as a storable capacity in an initial state of the secondary battery B, a measurement start voltage Vtl, and a measurement finish voltage Vth, are stored in the ROM of the μCOM 40. The measurement start voltage Vtl is set to a voltage value higher than a voltage between the both electrodes of the secondary battery B at the time of complete discharge. The measurement finish voltage Vth is set to a voltage value higher than the measurement start voltage Vtl. Further, since a change in the voltage between the both electrodes of the secondary battery B at the time of charge is large when the voltage approaches the voltage at the time of full charge, it is desirable that the measurement start voltage Vtl and the measurement finish voltage Vth be set to values close to the voltage at the time of full charge. Particularly, it is desirable that the measurement start voltage Vtl be greater than or equal to a value obtained by adding a value, which is half of a value obtained by subtracting a voltage at the time of complete discharge (Vempty) from a voltage at the time of full charge (Vfull), to the voltage at the time of complete discharge (Vtl=Vempty+(Vfull−Vempty)×0.5). Further, it is more desirable that the measurement start voltage Vtl be greater than or equal to a value obtained by adding a value, which is 80% of the value obtained by subtracting the voltage at the time of complete discharge (Vempty) from the voltage at the time of full charge (Vfull), to the voltage at the time of complete discharge (Vtl=Vempty+(Vfull−Vempty)×0.8). In the present embodiment, a lithium ion battery is used as the secondary battery B. The voltage at the time of complete discharge is set to 3.0 V, the voltage at the time of full discharge is set to 4.2 V, the measurement start voltage Vtl is set to 4.1 V, and the measurement finish voltage Vth is set to 4.2 V.

The μCOM 40 includes an output port PO connected to the charge part 15. The CPU of the μCOM 40 transmits the control signal to the charge part 15 through the output port PO and controls the charge part 15.

Further, the μCOM 40 includes an input port PI1, to which the signal from the first ADC 18 is input, and an input port PI2, to which the signal from the second ADC 19 is input. In the μCOM 40, the signals input to the input port PI1 and the input port PI2 are converted into information in a form that can be recognized by the CPU and transmitted to the CPU. Based on the information, the CPU detects the current value I flowing to the secondary battery B and a voltage V between the both electrodes of the secondary battery B when the charge part 15 outputs the charging current.

Further, the μCOM 40 has a communication port (not illustrated). This communication port is connected to an in-vehicle network (e.g., a CAN (Controller Area Network)) (not illustrated) and is connected to a display device, such as a terminal device for a vehicle maintenance, through the in-vehicle network. The CPU of the μCOM 40 transmits a signal indicating a detected SOH to the display device through the communication port and the in-vehicle network, and this display device displays a state of the secondary battery B, such as the SOH, based on the signal.

Next, an example of the battery state detection processing 1 in the μCOM 40 included in the aforementioned battery state detection device 1 will be described with reference to the flowchart in FIG. 2.

When receiving a charging start command of the secondary battery B from, for example, an electronic control device mounted on the vehicle through the communication port, the CPU of the μCOM 40 (hereinafter, simply referred to as “CPU”) transmits the control signal to the charge part 15 through the output port PO. The charge part 15 starts to feed a charging current Ic to the secondary battery B according to this control signal. This charging current Ic may have a constant current value or may have a current value that changes according to a charge state and the like. With this configuration, charge of the secondary battery B is started. Then, a process proceeds to the battery state detection processing illustrated in FIG. 2.

In the battery state detection processing, when the charging current Ic flows to the secondary battery B and the secondary battery B is being charged, the CPU waits until the voltage between the both electrodes of the secondary battery B reaches the measurement start voltage Vtl (N in S110). Specifically, the CPU periodically (e.g., every one second) detects the voltage V between the both electrodes of the secondary battery B based on the signal from the second input port PI2 and waits until the detected voltage V coincides with the measurement start voltage Vtl previously stored in the ROM.

Then, when the voltage V between the both electrodes of the secondary battery B reaches the measurement start voltage Vtl (Y in S110), the amount of power given to the secondary battery B is calculated and integrated (S120). Specifically, the CPU detects the current value I flowing to the secondary battery B based on the signal from the first input port PI1, detects the voltage V between the both electrodes of the secondary battery B based on the signal from the second input port PI2, calculates a power value P by multiplying these current value I and current value V, and integrates the power value P with a power value P calculated before that.

Then, the CPU repeats integration of the calculated power value P until the voltage V between the both electrodes of the secondary battery B reaches the measurement finish voltage Vth (N in S130). Specifically, the CPU periodically (e.g., every one second) detects the voltage V between the both electrodes of the secondary battery B based on the signal from the second input port PI2, and repeats calculation and integration of the power value P (S120) until the detected voltage V coincides with the measurement finish voltage Vth previously stored in the ROM.

Then, when the voltage between the both electrodes of the secondary battery B reaches the measurement finish voltage Vth (Y in S130), the CPU detects the SOH based on the integrated power value (an amount of integrated power Ps) (S140). Specifically, the CPU detects, as the SOH, a value obtained by dividing the amount of integrated power Ps by the initial power capacity Pf previously stored in the ROM. Alternatively, other than this, the SOH may be detected by previously storing, in the ROM, an information table that indicates a relation between the amount of integrated power Ps and the SOH and applying the amount of integrated power Ps to this information table. Then, after transmitting the detected SOH of the secondary battery B to the other devices through the communication port, the CPU finishes the battery state detection processing 1.

The μCOM 40 functions as the measurement start voltage detection unit by executing the processing in step S110 in the flowchart in FIG. 2, functions as the integrated power amount measurement unit by executing the processing in step S120, functions as the measurement finish voltage detection unit by executing the processing in step S130, and functions as the battery state detection unit by executing the processing in step S140.

As described above, according to the present embodiment, the charge part 15 charges the secondary battery B by feeding the predetermined charging current Ic thereto. The measurement start voltage detection unit detects that, during the charge by the charge part 15, the voltage V between the both electrodes of the secondary battery B has reached the predetermined measurement start voltage Vtl set higher than the voltage between the both electrodes of the secondary battery B at the time of complete discharge. The measurement finish voltage detection unit detects that, during the charge by the charge part 15, the voltage between the both electrodes of the secondary battery B has reached the predetermined measurement finish voltage Vth set higher than the measurement start voltage Vtl. The integrated power amount measurement unit measures the amount of integrated power Ps given to the secondary battery B in a period from the detection of the measurement start voltage Vtl to the detection of the measurement finish voltage Vth. Then, the battery state detection unit detects the SOH of the secondary battery B based on the amount of integrated power Ps measured by the integrated power amount measurement unit. Since it has been done in this way, in the secondary battery B being charged, the amount of integrated power Ps given to the secondary battery B is measured in a part of a period from the time of complete discharge to the time of full charge, and the SOH of the secondary battery is detected based on this amount of integrated power Ps. Accordingly, it is not necessary to provide discharge unit, and further, it is not necessary to measure over a whole period from the time of complete discharge to the time of full charge (including a charge state close to the full charge). As a result, it is possible to effectively suppress increase in manufacturing cost and increase in size of the device and to detect the SOH of the secondary battery B in a shorter time.

### Second Embodiment

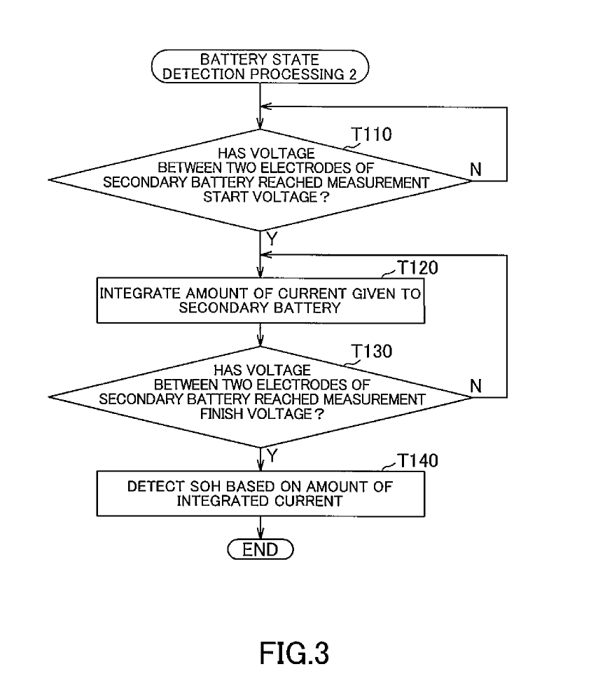

Hereinafter, a battery state detection device according to a second embodiment of the present invention will be described with reference to FIG. 3.

Instead of measuring the amount of integrated power Ps given to the secondary battery B in a part of the period from the time of complete discharge to the time of full charge in the aforementioned first embodiment, the battery state detection device of the present embodiment measures an amount of integrated current Is and detects an SOH of a secondary battery B based on the amount of integrated current Is. Specifically, a device configuration of the present embodiment is the same as the aforementioned battery state detection device 1, and instead of the battery state detection processing 1 illustrated in FIG. 2, a CPU of a μCOM 40 executes battery state detection processing 2 illustrated in FIG. 3. Accordingly, in the present embodiment, description of the device configuration is omitted, and only the battery state detection processing 2 in FIG. 3 will be described.

An example of the battery state detection processing 2 in the μCOM 40 included in the battery state detection device of the present embodiment will be described with reference to a flowchart in FIG. 3. Instead of the initial power capacity Pf, an initial current capacity If serving as a storable capacity in an initial state of the secondary battery B is stored in a ROM of the μCOM 40.

When receiving a charging start command of the secondary battery B from, for example, an electronic control device mounted on a vehicle through a communication port, the CPU of the μCOM 40 (hereinafter simply referred to as “CPU”) transmits a control signal to a charge part 15 through an output port PO. The charge part 15 starts to feed a charging current Ic to the secondary battery B according to this control signal. This charging current Ic may have a constant current value or may have a current value that changes according to a charge state and the like. With this configuration, charge of the secondary battery B is started. Then, a process proceeds to the battery state detection processing illustrated in FIG. 3.

In the battery state detection processing, when the charging current Ic flows to the secondary battery B and the secondary battery B is being charged, the CPU waits until a voltage between both electrodes of the secondary battery B reaches a measurement start voltage Vtl (N in T110). Specifically, the CPU periodically (e.g., every one second) detects a voltage V between the both electrodes of the secondary battery B based on a signal from a second input port PI2 and waits until the detected voltage V coincides with the measurement start voltage Vtl previously stored in the ROM.

Then, when the voltage V between the both electrodes of the secondary battery B reaches the measurement start voltage Vtl (Y in T110), an amount of current flowed into the secondary battery B is calculated and integrated (T120). Specifically, the CPU detects a current value I flowing to the secondary battery B based on a signal from a first input port PI1, and integrates the current value I with a current value I detected before that.

Then, the CPU repeats integration of the detected current value I until the voltage V between the both electrodes of the secondary battery B reaches a measurement finish voltage Vth (N in T130). Specifically, the CPU periodically (e.g., every one second) detects the voltage V between the both electrodes of the secondary battery B based on the signal from the second input port PI2, and repeats detection and integration of the current value I (T120) until the detected voltage V coincides with the measurement finish voltage Vth previously stored in the ROM.

Then, when the voltage between the both electrodes of the secondary battery B reaches the measurement finish voltage Vth (Y in T130), the CPU detects the SOH based on the integrated current value (the amount of integrated current Is) (T140). Specifically, the CPU detects, as the SOH, a value obtained by dividing the amount of integrated current Is by the initial current capacity If previously stored in the ROM. Alternatively, other than this, the SOH may be detected by previously storing, in the ROM, an information table that indicates a relation between the amount of integrated current Is and the SOH and applying the amount of integrated current Is to this information table. Then, after transmitting the detected SOH of the secondary battery B to the other devices through the communication port, the CPU finishes the battery state detection processing 2.

The μCOM 40 functions as measurement start voltage detection unit by executing the processing in step T110 in the flowchart in FIG. 3, functions as integrated current amount measurement unit by executing the processing in step T120, functions as measurement finish voltage detection unit by executing the processing in step T130, and functions as battery state detection unit by executing the processing in step T140.

As described above, according to the present embodiment, the charge part 15 charges the secondary battery B by feeding the predetermined charging current Ic thereto. The measurement start voltage detection unit detects that, during the charge by the charge part 15, the voltage V between the both electrodes of the secondary battery B has reached the predetermined measurement start voltage Vtl set higher than the voltage between the both electrodes of the secondary battery B at the time of complete discharge. The measurement finish voltage detection unit detects that, during the charge by the charge part 15, the voltage V between the both electrodes of the secondary battery B has reached the predetermined measurement finish voltage Vth set higher than the measurement start voltage Vtl. The integrated current amount measurement unit measures the amount of integrated current Is flowed into the secondary battery B in a period from the detection of the measurement start voltage Vtl to the detection of the measurement finish voltage Vth. The battery state detection unit detects a state of the secondary battery B based on the amount of integrated current Is measured by the integrated current amount measurement unit. Since it has been done in this way, in the secondary battery B being charged, the amount of integrated current Is given to the secondary battery B is measured in a part of a period from the time of complete discharge to the time of full charge and the state of the secondary battery B is detected based on this amount of integrated current Is. Accordingly, it is not necessary to provide discharge unit, and further, it is not necessary to measure over a whole period from the time of complete discharge to the time of full charge (including a charge state close to the full charge). As a result, it is possible to effectively suppress increase in manufacturing cost and increase in size of the device and to detect the state of the secondary battery in a shorter time.

As described above, the present invention has been described by way of the preferred embodiments. However, the battery state detection device of the present invention is not limited to the configurations of these embodiments.

For example, in each of the aforementioned embodiments, it is configured that the SOH of the secondary battery B is detected as the state of the secondary battery. However, the present invention is not limited to this. Since rising speed of the voltage between the electrodes of the secondary battery being charged, i.e., the aforementioned amount of integrated power Ps and amount of integrated current Is, have a correlation with internal resistance of the secondary battery as well, it may be configured that the internal resistance, instead of the SOH, is detected as the state of the secondary battery.

Further, in each of the aforementioned embodiments, it is configured that the battery state detection device detects the SOH of the one secondary battery B. However, the present invention is not limited to this. For example, it may be configured that a multiplexer is provided at a tip of the battery state detection device and that the battery state detection device is connected with a plurality of secondary batteries B by switching the multiplexer.

It should be noted that the aforementioned embodiments only indicate typical embodiments of the present invention and the present invention is not limited to the embodiments. In other words, following conventionally known knowledge, one skilled in art can implement by modifying the present invention in various ways without deviating from a gist thereof. As long as having the configuration of the battery state detection device of the present invention, such a modification is certainly included in a category of the present invention.

### REFERENCE SIGNS LIST

1 battery state detection device
11 first comparator (time measurement start voltage detection unit)
12 second comparator (time measurement finish voltage detection unit)
13 reference voltage generation part
15 charge part (charge unit)
40 microcomputer (integrated power amount measurement unit, integrated current amount measurement unit, battery state detection unit)
B secondary battery
Vtl time measurement start voltage
Vth time measurement finish voltage

1. A battery state detection device for detecting a state of a secondary battery, comprising:
a charge unit for charging the secondary battery by feeding a predetermined charging current to the secondary battery;
a measurement start voltage detection unit for detecting whether, during charging by the charge unit, a voltage between both electrodes of the secondary battery reaches a predetermined measurement start voltage higher than a voltage between the both electrodes of the secondary battery at a time of complete discharge;
a measurement finish voltage detection unit for detecting whether, during charging by the charge unit, the voltage between the both electrodes of the secondary battery reaches a predetermined measurement finish voltage higher than the measurement start voltage;
an integrated power amount measurement unit for measuring an amount of an integrated power given to the secondary battery in a period from the detection of the measurement start voltage to the detection of the measurement finish voltage; and
a battery state detection unit for detecting a state of the secondary battery based on the amount of integrated power measured by the integrated power amount measurement unit,
wherein the measurement start voltage is greater than or equal to a value obtained by adding a value, which is half of a value obtained by subtracting a voltage at the time of complete discharge from a voltage at a time of full charge of the secondary battery, to the voltage at the time of complete discharge.

2. A battery state detection device for detecting a state of a secondary battery, comprising:
a charge unit for charging the secondary battery by feeding a predetermined charging current to the secondary battery;
a measurement start voltage detection unit detecting whether, during charging by the charge unit, a voltage between both electrodes of the secondary battery reaches a predetermined measurement start voltage higher than a voltage between the both electrodes of the secondary battery at a time of complete discharge;
a measurement finish voltage detection unit for detecting whether, during charging by the charge unit, the voltage between the both electrodes of the secondary battery reaches a predetermined measurement finish voltage higher than the measurement start voltage;
an integrated current amount measurement unit for measuring an amount of integrated current flowed into the secondary battery in a period from the detection of the measurement start voltage to the detection of the measurement finish voltage; and
a battery state detection unit for detecting a state of the secondary battery based on the amount of integrated current measured by the integrated current amount measurement unit,
wherein the measurement start voltage is greater than or equal to a value obtained by adding a value, which is half of a value obtained by subtracting a voltage at the time of complete discharge from a voltage at a time of full charge of the secondary battery, to the voltage at the time of complete discharge.

3. The battery state detection device according to claim 1, wherein the measurement start voltage is greater than or equal to a value obtained by adding a value, which is 80% of the value obtained by subtracting the voltage at the time of complete discharge from the voltage at the time of full charge of the secondary battery, to the voltage at the time of complete discharge.

4. The battery state detection device according to claim 2, wherein the measurement start voltage is greater than or equal to a value obtained by adding a value, which is 80% of the value obtained by subtracting the voltage at the time of complete discharge from the voltage at the time of full charge of the secondary battery, to the voltage at the time of complete discharge.
